(19) United States
(12) Patent Application Publication
(10) Pub. No.: US 2025/0244684 A1
(43) Pub. Date: Jul. 31, 2025

(54) SUBSTARATE PROCESSING APPARATUS WITH VUV INTENSITY CONTROL

(71) Applicant: ASM IP Holding B.V., Almere (NL)

(72) Inventors: Takahiro Murakami, Tokyo (JP); Chia Wen Shih, Tokyo (JP)

(21) Appl. No.: 19/036,574

(22) Filed: Jan. 24, 2025

Related U.S. Application Data
(60) Provisional application No. 63/626,157, filed on Jan. 29, 2024.

(51) Int. Cl. G03F 7/00; G03F 7/20

(52) U.S. Cl. CPC G03F 7/7085; G03F 7/2051; G03F 7/70016; G03F 7/7055; G03F 7/70825; G03F 7/70875

(57) ABSTRACT

A substrate processing apparatus may be presented. The apparatus comprising a lamp unit configured to emit a UV (ultraviolet) light, a lamp compartment configured to contain one or more lamp units, a processing chamber with a susceptor and configured to process a substrate, the susceptor is configured to support a substrate for processing, a separation window disposed between the lamp compartment and the processing chamber, and configured to be transparent for a light from the UV lamp to reach to the substrate, a measurement unit disposed in a wall of the processing chamber, the measurement unit configured to measure a light intensity in the processing chamber, and a power controller electrically connected to the measurement unit and configured to adjust a supply of power to the lamp compartment according to the light intensity measured by the measurement unit.

### CROSS-REFERENCE TO RELATED APPLICATIONS

This application claims priority to U.S. Provisional Patent Application Ser. No. 63/626,157 filed Jan. 29, 2024 and titled SUBSTRATE PROCESSING APPARATUS WITH VUV INTENSITY CONTROL, the disclosure of which is hereby incorporated by reference in its entirety.

### FIELD OF INVENTION

The present disclosure relates to an apparatus for processing a substrate, particularly to an apparatus which can adjust and control the intensity of Vacuum UV (Ultraviolet) light which may be applied for treating film UV irradiation.

### BACKGROUND OF THE DISCLOSURE

UV irradiation may be applied to various processes for treating different types of film. The UV treatment may be more efficient and operates at lower temperature compared to thermal treatment.

However, the vacuum ultraviolet (VUV) light intensity in the process chamber may be largely affected by quartz window transmission efficiency and may not be controlled by the intensity sensor in the VUV irradiation assembly.

Furthermore, the VUV light has high energy level and this may generate defects inside the window which increase the light absorption rate of the quartz window. Usually, the transmission of the quartz window decays over irradiation time.

Therefore, the present disclosure presents a way to monitor the intensity of vacuum ultraviolet light inside the process chamber.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a substrate processing apparatus comprising: a lamp unit configured to emit a UV light; a lamp compartment configured to contain one or more lamp units; a processing chamber with a susceptor and configured to process a substrate, the susceptor is configured to support a wafer for processing; a separation window disposed between the lamp compartment and the processing chamber, and configured to be transparent for a light from the UV lamp to reach to the substrate; a measurement unit disposed in a wall of the processing chamber, the measurement unit configured to measure a light intensity in the processing chamber; and a power controller electrically connected to the measurement unit and configured to adjust a supply of power to the lamp compartment according to the light intensity measured by the measurement unit.

In an aspect, the lamp unit comprises a UV lamp for emitting the UV light; an intensity sensor configured to sense and measure the light intensity of the UV light; and a power regulator electrically connected to the intensity sensor and configured to control a power supplied to the UV lamp according to the light intensity measured by the intensity sensor.

In an aspect, the measurement unit comprises a tube disposed through a side wall of the processing chamber; a fluorescent body disposed at one end of the tube and configured to convert a UV light into a visible light; an optical fiber disposed at the other end of the tube and configured to guide the visible light; and a light sensor connected to the optical fiber and configured to sense and measure a visible light intensity received from the optical fiber.

In an aspect, the measurement unit further comprising a fixing jig configured to seal and attach the tube onto the wall of the processing chamber.

In an aspect, the fluorescent body is tilted at an angle of a first degree from a vertical.

In an aspect, the first degree ranges from 0° to 45°.

In an aspect, the tube is tilted at an angle of a second degree to a horizon.

In an aspect, the fluorescent body comprises one of YAG [Y₃Al₅O₁₂:Ce³⁺], LSN [La₃Si₆N₁₁:Ce³⁺], LYSN [(La,Y)₃Si₆N₁₁:Ce³⁺], CASN [CaAlSiN₃:Eu²⁺], SCASN [(Sr,Ca)AlSiN₃:Eu²⁺], CSO [CaSc₂O₄:Ce³⁺], β-SiAlON [(Si,Al)₃(O,N)₄:Eu²⁺], GYAG [Y₃(Al,Ga)₅O₁₂:Ce³⁺], LuAG [Lu₃Al₅O₁₂:Ce³⁺], SBCA [(Sr,Ba)₁₀(PO4)₆Cl₂:Eu²⁺] or any mixture of them.

In an aspect, the separation window is made of one of quartz, glass, crystal or a mixture of at least one of them.

In an aspect, an inside of the tube is covered with a material that reflects visible light.

In an aspect, a sectional shape of the tube is one of circle, rectangle, pentagon, hexagon or polygon larger than hexagon.

In accordance with another embodiment there may be provided, a substrate processing apparatus comprising: a lamp unit configured to emit a UV light, comprising a UV lamp for emitting the UV light; an intensity sensor configured to sense and measure the light intensity of the UV light; and a power regulator electrically connected to the intensity sensor and configured to control a power supplied to the UV lamp according to the light intensity measured by the intensity sensor; a lamp compartment configured to contain one or more lamp units; a processing chamber with a susceptor and configured to process a substrate, the susceptor is configured to support and/or heat the substrate for processing; a gas inlet disposed at one side of the processing chamber and configured to provide a gas for processing the substrate; an exhaust duct disposed at the opposite side of the gas inlet and configured to pump out the gas from the processing chamber; a separation window disposed between the lamp compartment and the processing chamber, and configured to be transparent for a light from the UV lamp to reach to the substrate; a measurement unit disposed in a wall of the processing chamber and configured to measure a light intensity in the processing chamber; and a power controller electrically connected to the measurement unit and configured to adjust a supply of power to the lamp compartment according to the light intensity measured by the measurement unit.

In an aspect, the measurement unit comprises: a tube disposed through a side wall of the processing chamber; a fluorescent body disposed at one end of the tube and configured to convert a UV light into a visible light; an optical fiber disposed at the other end of the tube and configured to guide the visible light; and a light sensor connected to the optical fiber and configured to sense and measure a visible light intensity received from the optical fiber.

In an aspect, the measurement unit further comprising: a fixing jig configured to seal and attach the tube onto the wall of the processing chamber.

In an aspect, the fluorescent body is tilted at an angle of a first degree from a vertical.

In an aspect, the first degree ranges from 0° to 45°.

In an aspect, the tube is tilted at a predetermined angle to a horizon.

In an aspect, the fluorescent body comprises one of YAG [Y₃Al₅O₁₂:Ce³⁺], LSN [La₃Si₆N₁₁:Ce³⁺], LYSN [(La,Y)₃Si₆N₁₁:Ce³⁺], CASN [CaAlSiN₃:Eu²⁺], SCASN [(Sr,Ca)AlSiN₃:Eu²⁺], CSO [CaSc₂O₄:Ce³⁺], β-SiAlON [(Si,Al)₃(O,N)₄:Eu²⁺], GYAG [Y₃(Al,Ga)₅O₁₂:Ce³⁺], LuAG [Lu₃Al₅O₁₂:Ce³⁺], SBCA [(Sr,Ba)₁₀(PO4)₆Cl₂:Eu²⁺] or any mixture of them.

In an aspect, the separation window is made of one of quartz, glass, crystal or a mixture of at least one of them.

In an aspect, an inside of the tube is covered with a material that reflects visible light.

In an aspect, a sectional shape of the tube is one of circle, rectangle, pentagon, hexagon or polygon larger than hexagon.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a view of a substrate processing apparatus according to an embodiment of the present disclosure.

FIG. 2 (a) shows an overview of a measurement unit in a mode according to an embodiment of the present disclosure; (b) shows an overview of a measurement unit in another mode according to another embodiment of the present disclosure; (c) shows UV light emitted from UV lamps coming down and hitting a fluorescent body.

FIG. 3 (a) shows a circular section view of a tube used in the present disclosure according to an embodiment of the present disclosure; (b) shows a rectangular section view of a tube used in the present disclosure according to another embodiment of the present disclosure; (c) shows a pentagonal section view of a tube used in the present disclosure according to another embodiment of the present disclosure; (d) shows a hexagonal section view of a tube used in the present disclosure according to another embodiment of the present disclosure.

FIG. 4 shows another view of a substrate processing apparatus according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, UV lamp and VUV lamp has the same or similar meaning in the context.

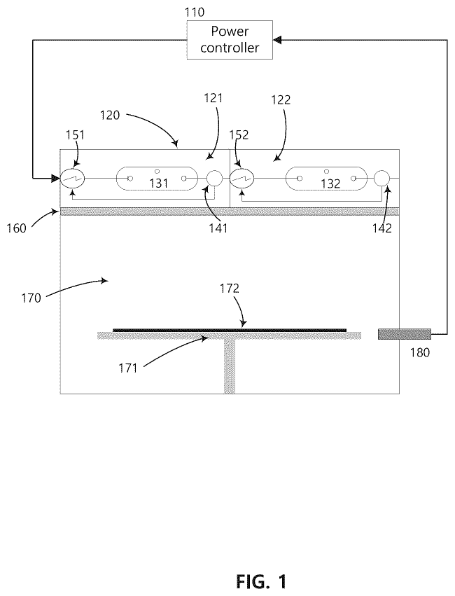

FIG. 1 illustrates an overview of a substrate processing apparatus according to an embodiment of the present disclosure.

A substrate processing apparatus according to an embodiment of the present disclosure may comprise a lamp compartment 120, a processing chamber 170, a substrate susceptor 171, a separation window 160, one or more lamp units (121, 122), a measurement unit 180, and a power controller 110.

A lamp unit (121, 122) may comprise a UV lamp (131, 132), an intensity sensor (141, 142), and a power regulator (151, 152).

The UV lamp (131, 132) may emit UV light. The intensity sensor (141, 142) may sense the intensity of the UV light emitted from the UV lamp (131, 132). According to the result of the sensing of the intensity sensor (141, 142), a power regulator (151, 152) adjusts the power supplied to the UV lamp (131, 132). The power regulator (151,152) may receive power supplied from the power controller 110 and may also regulate the distribution of the power to the UV lamp (131, 132).

In FIG. 1, 2 lamp units (121, 122) in the lamp compartment 120 is shown as an example. However, there may be one or more lamp units in the lamp compartment 120.

Below the lamp compartment 120, a processing chamber 170 may be placed. In the processing chamber 170, a substrate susceptor 171 may be placed to support and/or heat a substrate 172 for UV light treatment. Between the lamp compartment 120 and the processing chamber 170, a separation window 160 may be placed. The separation window 160 may be transparent enough to let the UV light from each of the lamp unit (121, 122) pass through into the processing chamber 170. Therefore, the level of UV-transparency level of the window 160 is important in substrate quality.

Each intensity sensor (141, 142) may sense mostly the intensity within the lamp unit it is in. However, it is the UV light's intensity in the processing chamber 170 that may be more important than that of the lamp unit (121, 122) because the UV light intensity in the processing chamber 170 may be the actual factor in substrate treatment. To sense and measure the UV light intensity in the processing chamber 170, a measurement unit 180 may be placed on a wall of the processing chamber 170.

The measurement unit 180 may be installed through the processing chamber wall as shown in FIG. 1. The measurement unit 180 may be installed at the same or similar height of the substrate susceptor 171 so that it may measure the actual UV light intensity of substrate treatment.

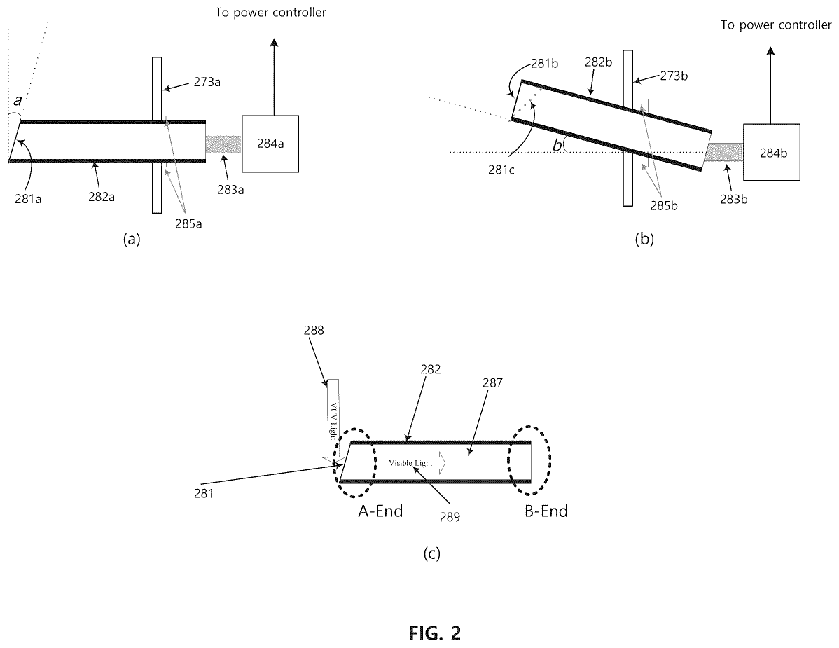

FIG. 2 (a) illustrates one mode of measurement unit. The measurement unit may comprise a tube 282a, a fluorescent body 281a placed at the inside end of the tube 282a, an optical fiber 283a connected to the other end of the tube 282a, and a light sensor 284a.

The fluorescent body 281a may convert a UV light into a visible light. In FIG. 2 (c), the UV light 288 emitted from UV lamps comes down and hits the fluorescent body 281. The fluorescent body 281 may be a very thin membrane like film with chemically treated with fluorescent materials. It is well known that fluorescent materials when shone on UV light emits visible light. By this chemical reaction, the UV light 288 turns into a visible light 289 and this visible light goes along the light guide 287 formed by the tube 282. The fluorescent materials may be one of Y₃Al₅O₁₂:Ce³⁺(YAG), La₃Si₆N₁₁:Ce³⁺(LSN), (La,Y)₃Si₆N₁₁:Ce³⁺(LYSN), CaAlSiN₃:Eu²⁺ (CASN), (Sr,Ca)AlSiN₃:Eu²⁺(SCASN), CaSc₂O₄:Ce³⁺(CSO), (Si,Al)₃(O,N):Eu²⁺(β-SiAlON), Y₃(Al,Ga)₅O₁₂:Ce³⁺(GYAG), Lu₃Al₅O₁₂:Ce³⁺(LuAG), (Sr,Ba)₁₀(PO4)₆Cl₂:Eu²⁺ (SBCA) or any mixture of them.

If the fluorescent body 281a may be installed vertically, then UV light emitted from the above may not touch the fluorescent body. Therefore, the fluorescent body 281a may be tilted to a certain degree to the vertical to get enough and exact amount of UV light (i.e., visible light after all) for sensing the UV intensity. This tilted angle (denoted as ‘a’) in FIG. 2 (a) may vary from 0° to 45°.

In FIG. 2 (b), the measurement unit may be installed and it may be tilted to another certain degree to the horizon. The tube 282b may be inclined so that the fluorescent body 281b may be exposed to the UV light comes down from the above. The degree of inclination of tube 282b (denoted as ‘b’) may vary from 0° to 45°. In this case the tilt of fluorescent body 281b may not be needed but may be installed when needed.

The tube (282a, 282b) may be installed through a processing chamber's wall (273a, 273b). Therefore, a fastening unit which may seal and fasten the wall (273a, 273b) and the tube (282a, 282b) may be needed and fixing jig (285a, 285b) may be used. The fixing jig (285a, 285b) may be a seal O-ring or any other things that can seal and fasten.

The light sensor (284a, 284b) may be setup with a predetermined level of light intensity. This predetermined level of intensity may vary to meet system requirements.

Optical fiber (283a, 283b) may link the tube (282a, 282b) and the light sensor (284a, 284b). Visible light 289 emitted from the fluorescent body (281, 281a, 281b) may follow the light guide 287 until it reaches B-End (The other end of the tube). When the visible light 289 reaches ‘B-end’, the visible light 289 goes into the optical fiber (283a, 283b) until it reaches to the light sensor (284a, 284b). For this purpose, the light guide 287 (inside of the tube 282, 282a, 282b) may be covered with a material which may reflect (visible) light for conveying the visible light 289 intact to the light sensor (284a, 284b).

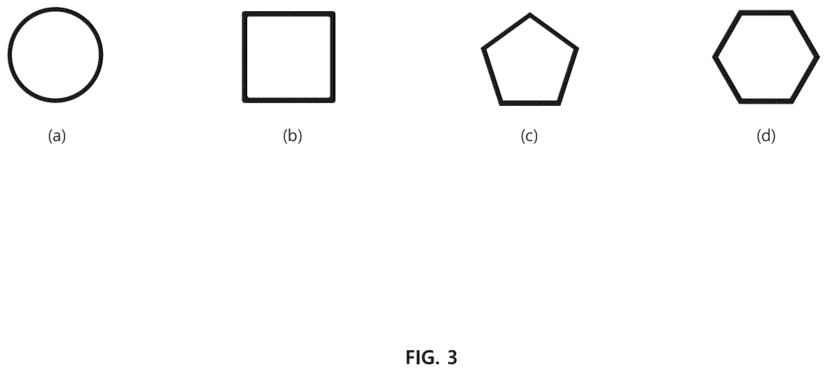

The measurement unit 180's sectional shapes may be illustrated in FIG. 3 (a)^{˜}(d). A tube with round sectional shape, as shown in FIG. 3 (a), may be used but it may rotate around the tube's circular axis. Therefore, there may be used other sectional shapes for the tube. FIG. 3 (b), FIG. 3 (c) and FIG. 3 (d) may be the tube's sectional shapes such as rectangle, pentagon, hexagon, respectively. Although the shapes may not be illustrated, polygons higher than hexagon, such as heptagon and octagon and so on, may be used for the tube (282, 282a, 282b) in the measurement unit 180.

The power controller 110 in FIG. 1 receives the feedback signal from the light sensor (284a, 284b) from the measurement unit 180 and controls the power supplied to the UV lamps in the lamp compartment 120.

The VUV lamps may be generally decayed as the usage time goes by. Therefore, the UV light status (i.e., intensity) should be checked on regularly so that the substrate treatment quality may be good and efficient and the present disclosure presents a good way to measure and sense the actual UV light intensity inside of the processing chamber.

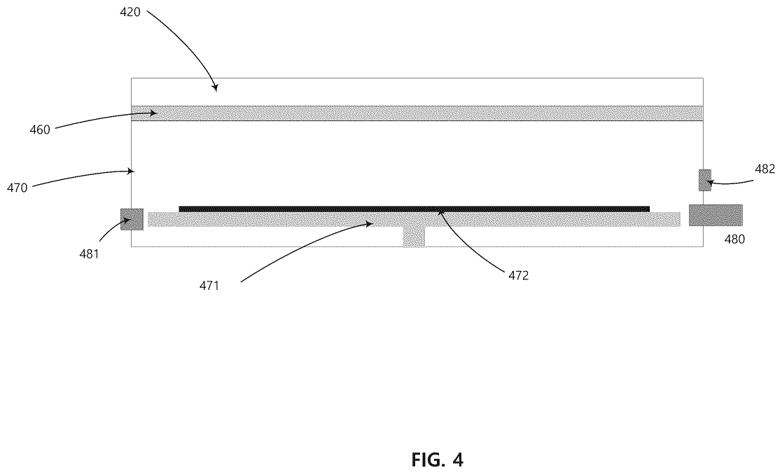

FIG. 4 illustrates a substrate processing apparatus with VUV lamps according to another embodiment of the present disclosure.

For simplicity, lamp units (along with UV lamp, intensity sensor, and power regulator inside of each of them) in a lamp compartment 420 and a power controller are not drawn.

The lamp compartment 420 may emit UV light into a processing chamber 470 through a separation window 460. A gas inlet 482 may be disposed at one side of the processing chamber 470 for providing a gas into the processing chamber 470 for processing a substrate 472. In the processing chamber 470, a susceptor 471 may be disposed to support and/or heat the substrate 472. An exhaust duct 481 may be disposed at the opposite side of the gas inlet 482 on the processing chamber 470 for exhausting the gas from the processing chamber 470. The measurement unit 480 may be disposed at a wall of the processing chamber 470. The gas inlet 482 may comprise more than one holes on the wall of the processing chamber 470.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A substrate processing apparatus comprising:
a lamp unit configured to emit a UV light, comprising:
a UV lamp for emitting the UV light;
an intensity sensor configured to sense and measure the light intensity of the UV light; and
a power regulator electrically connected to the intensity sensor and configured to control a power supplied to the UV lamp according to the light intensity measured by the intensity sensor;
a lamp compartment configured to contain one or more lamp units;
a processing chamber with a susceptor and configured to process a substrate, the susceptor is configured to support and/or heat the substrate for processing;
a separation window disposed between the lamp compartment and the processing chamber, and configured to be transparent for a light from the UV lamp to reach to the substrate;
a measurement unit disposed in a wall of the processing chamber, the measurement unit configured to measure a light intensity in the processing chamber; and
a power controller electrically connected to the measurement unit and configured to adjust a supply of power to the lamp compartment according to the light intensity measured by the measurement unit.

2. The substrate processing apparatus according to claim 1, wherein the measurement unit comprises:
a tube disposed through a side wall of the processing chamber;
a fluorescent body disposed at one end of the tube and configured to convert a UV light into a visible light;
an optical fiber disposed at the other end of the tube and configured to guide the visible light; and
a light sensor connected to the optical fiber and configured to sense and measure a visible light intensity received from the optical fiber.

3. The substrate processing apparatus according to claim 2, the measurement unit further comprising:
a fixing jig configured to seal and attach the tube onto the wall of the processing chamber.

4. The substrate processing apparatus according to claim 2, wherein the fluorescent body is tilted at an angle of a first degree from a vertical.

5. The substrate processing apparatus according to claim 4, wherein the first degree ranges from 0° to 45°.

6. The substrate processing apparatus according to claim 2, wherein the tube is tilted at a predetermined angle to a horizon.

7. The substrate processing apparatus according to claim 2, wherein the fluorescent body comprises one of YAG [Y₃Al₅O₁₂:Ce³⁺], LSN [La₃Si₆N₁₁:Ce³⁺], LYSN [(La,Y)₃Si₆N₁₁:Ce³⁺], CASN [CaAlSiN₃:Eu²⁺], SCASN [(Sr,Ca)AlSiN₃:Eu²⁺], CSO [CaSc₂O₄:Ce³⁺], β-SiAlON [(Si,Al)₃(O,N)₄:Eu²⁺], GYAG [Y₃(Al,Ga)₅O₁₂:Ce³⁺], LuAG [Lu₃Al₅O₁₂:Ce³⁺], SBCA [(Sr,Ba)₁₀(PO4)₆Cl₂:Eu²⁺] or any mixture of them.

8. The substrate processing apparatus according to claim 1, wherein the separation window is made of one of quartz, glass, crystal or a mixture of at least one of them.

9. The substrate processing apparatus according to claim 2, wherein an inside of the tube is covered with a material that reflects the visible light.

10. The substrate processing apparatus according to claim 2, wherein a sectional shape of the tube is one of circle, rectangle, pentagon, hexagon or polygon larger than hexagon.

11. A substrate processing apparatus comprising:
a lamp unit configured to emit a UV light, comprising:
a UV lamp for emitting the UV light;
an intensity sensor configured to sense and measure the light intensity of the UV light; and
a power regulator electrically connected to the intensity sensor and configured to control a power supplied to the UV lamp according to the light intensity measured by the intensity sensor;
a lamp compartment configured to contain one or more lamp units;
a processing chamber with a susceptor and configured to process a substrate, the susceptor is configured to support and/or heat the substrate for processing;
a gas inlet disposed at one side of the processing chamber and configured to provide a gas for processing the substrate;
an exhaust duct disposed at an opposite side of the gas inlet and configured to pump out the gas from the processing chamber;
a separation window disposed between the lamp compartment and the processing chamber, and configured to be transparent fora light from the UV lamp to reach to the substrate;
a measurement unit disposed in a wall of the processing chamber and configured to measure a light intensity in the processing chamber; and
a power controller electrically connected to the measurement unit and configured to adjust a supply of power to the lamp compartment according to the light intensity measured by the measurement unit.

12. The substrate processing apparatus according to claim 11, wherein the measurement unit comprises:
a tube disposed through a side wall of the processing chamber;
a fluorescent body disposed at one end of the tube and configured to convert a UV light into a visible light;
an optical fiber disposed at the other end of the tube and configured to guide the visible light; and
a light sensor connected to the optical fiber and configured to sense and measure a visible light intensity received from the optical fiber.

13. The substrate processing apparatus according to claim 12, the measurement unit further comprising:
a fixing jig configured to seal and attach the tube onto the wall of the processing chamber.

14. The substrate processing apparatus according to claim 12, wherein the fluorescent body is tilted at an angle of a first degree from a vertical.

15. The substrate processing apparatus according to claim 14, wherein the first degree ranges from 0° to 45°.

16. The substrate processing apparatus according to claim 12, wherein the tube is tilted at a predetermined angle to a horizon.

17. The substrate processing apparatus according to claim 12, wherein the fluorescent body comprises one of YAG [Y₃Al₅O₁₂:Ce³⁺], LSN [La₃Si₆N₁₁:Ce³⁺], LYSN [(La,Y)₃Si₆N₁₁:Ce³⁺], CASN [CaAlSiN₃:Eu²⁺], SCASN [(Sr,Ca)AlSN₃:Eu²⁺], CSO [CaSc₂O₄:Ce³⁺], β-SiAlON [(Si,Al)₃(O,N)₄:Eu²⁺], GYAG [Y₃(Al,Ga)₅O₁₂:Ce³⁺], LuAG [Lu₃Al₅O₁₂:Ce³⁺], SBCA [(Sr,Ba)₁₀(PO4)₆Cl₂:Eu²⁺] or any mixture of them.

18. The substrate processing apparatus according to claim 11, wherein the separation window is made of one of quartz, glass, crystal or a mixture of at least one of them.

19. The substrate processing apparatus according to claim 12, wherein an inside of the tube is covered with a material that reflects the visible light.

20. The substrate processing apparatus according to claim 12, wherein a sectional shape of the tube is one of circle, rectangle, pentagon, hexagon or polygon larger than hexagon.
